(19) United States
(12) Patent Application Publication
(10) Pub. No.: US 2005/0053247 A1
(43) Pub. Date: Mar. 10, 2005

(54) Audio speaker crossover having two or more filter housings

(76) Inventors: James Petronio, Santa Monica, CA (US); Leif Blackmon, Medfield, MA (US)

Correspondence Address: WOLF GREENFIELD & SACKS, PC;FEDERAL RESERVE PLAZA, 600 ATLANTIC AVENUE, BOSTON, MA, 02210-2211, US

(21) Appl. No.: 10/754,469

(22) Filed: Jan. 9, 2004

Related U.S. Application Data
(60) Provisional application No. 60/438,851, filed on Jan. 9, 2003.

(51) Int. Cl. H03G 5/00; H04R 5/00

(52) U.S. Cl. 381/99; 381/17

(57) ABSTRACT

A crossover assembly is provided for connection in an audio system including an amplifier and two or more transducers. The crossover assembly includes a tweeter filter assembly and a woofer filter assembly. The tweeter filter assembly includes a tweeter filter housing, a tweeter filter mounted in the tweeter filter housing, an input port, an output port and a first mechanical connector. The woofer filter assembly includes a woofer filter housing, a woofer filter mounted in the woofer filter housing, an input port, an output port and a second mechanical connector. The tweeter and woofer filter assemblies are dockable by interengaging the first and second mechanical connectors and are separable by disengaging the first and second mechanical connectors.

### CROSS-REFERENCE TO RELATED APPLICATION

This application claims the benefit of Provisional Application Ser. No. 60/438,851, filed on Jan. 9, 2003, which is hereby incorporated by reference.

### FIELD OF THE INVENTION

This invention relates to audio speaker systems and, more particularly, to an audio speaker crossover assembly having separable and dockable filter assemblies.

### BACKGROUND OF THE INVENTION

Conventional audio speakers include a high frequency transducer known as a tweeter and a low frequency transducer known as a woofer. Typically, the signals which drive the tweeter and the woofer are derived from a single signal, such as an amplifier output signal. A tweeter driver signal and a woofer driver signal are derived from the amplifier output signal using an electronic component known as a crossover. In conventional speaker systems, the crossover includes a high pass filter, or tweeter filter, which filters the amplifier output signal to provide the tweeter driver signal and a low pass filter, or woofer filter, which filters the amplifier output signal to provide the woofer driver signal.

In typical home speakers, the crossover is mounted in a housing such as a speaker cabinet or enclosure with a tweeter and a woofer. In other applications, spatial constraints make a single, relatively large housing undesirable. Accordingly, the crossover may be located in a housing that is separate from the tweeter and the woofer. For example, in vehicle applications, the spatial separation between a crossover and a tweeter and/or a woofer may be several feet.

In applications where the crossover is spatially separated from the tweeter and the woofer, the crossover has utilized a housing which provides protection for the filter electronics and which permits mounting of the crossover to a component of the vehicle. The physical configuration of a conventional crossover includes filter electronics for the tweeter filter and the woofer filter mounted in a single housing. In vehicle applications, the crossover, the tweeter and the woofer can each be mounted in suitable locations as determined, for example, by the design and location of mechanical and electrical components of a particular vehicle model.

FIG. 1 is a schematic block diagram of an example of a prior art speaker 10 including an amplifier 11, a crossover 12 having a tweeter filter 22 and a woofer filter 24, a tweeter 13, and a woofer 14. Crossover 12 has an input port 26 for receiving an audio signal from amplifier 11, a tweeter output port 27 which provides a tweeter driver signal to tweeter 13 and a woofer output port 28 which provides a woofer driver signal to woofer 14. It will be understood that speaker 10 corresponds to one branch of a speaker system. Typically, a speaker system includes two or more branches, for example, left and right branches in both the front and the rear of the vehicle.

Prior art speakers provide generally satisfactory performance. However, it is desirable to provide speakers wherein one or a few configurations can be utilized in multiple different vehicles and in other applications having spatial constraints. Accordingly, there is a need for improved crossover configurations.

### SUMMARY OF THE INVENTION

According to a first aspect of the invention, a crossover assembly is provided for connection in an audio system including an amplifier and two or more transducers. The crossover assembly comprises a first filter assembly including a first filter mounted in a first housing, and a second filter assembly including a second filter mounted in a second housing. The first and second filter assemblies are mechanically dockable to form a single crossover unit and are mechanically separable to facilitate mounting in different locations. The first filter may comprise a tweeter filter, and the second filter may comprise a woofer filter.

The first filter assembly may include a first mechanical connector, and the second filter assembly may include a second mechanical connector. The first and second mechanical connectors are interengageable for mechanical docking of the first and second filter assemblies and are disengageable for mechanical separation of the first and second filter assemblies. The first and second mechanical connectors may comprise snap-fit connectors and may be integral components of the first and second housings, respectively.

According to a second aspect of the invention, a crossover assembly is provided for connection in an audio system including an amplifier and two or more transducers. The crossover assembly comprises a tweeter filter assembly and a woofer filter assembly. The tweeter filter assembly includes a tweeter filter housing, a tweeter filter mounted in the tweeter filter housing, an input port, an output port and a first mechanical connector. The woofer filter assembly includes a woofer filter housing, a woofer filter mounted in the woofer filter housing, an input port, an output port and a second mechanical connector. The tweeter and woofer filter assemblies are dockable by interengaging the first and second mechanical connectors and are separable by disengaging the first and second mechanical connectors.

According to a third aspect of the invention, a filter assembly is provided for connection in an audio system including an amplifier and a transducer. The filter assembly comprises a filter housing including a mechanical connector, a single crossover filter mounted in the filter housing, an input port for connecting the crossover filter to the amplifier, and an output port for connecting the crossover filter to the transducer. The filter assembly is mechanically dockable to another filter assembly using the mechanical connector.

### BRIEF DESCRIPTION OF THE DRAWINGS

For a better understanding of the present invention, reference is made to the accompanying drawings, which are incorporated herein by reference and in which:

FIG. 1 is a schematic block diagram of a prior art speaker;

FIG. 2 is a schematic block diagram of a speaker in accordance with an embodiment of the invention;

FIG. 3 is a perspective view of a crossover assembly in accordance with an embodiment of the invention, shown in the docked configuration;

FIG. 4 is a right-side perspective view of a filter assembly in accordance with an embodiment of the invention; and

FIG. 5 is a left-side perspective view of the filter assembly of FIG. 4.

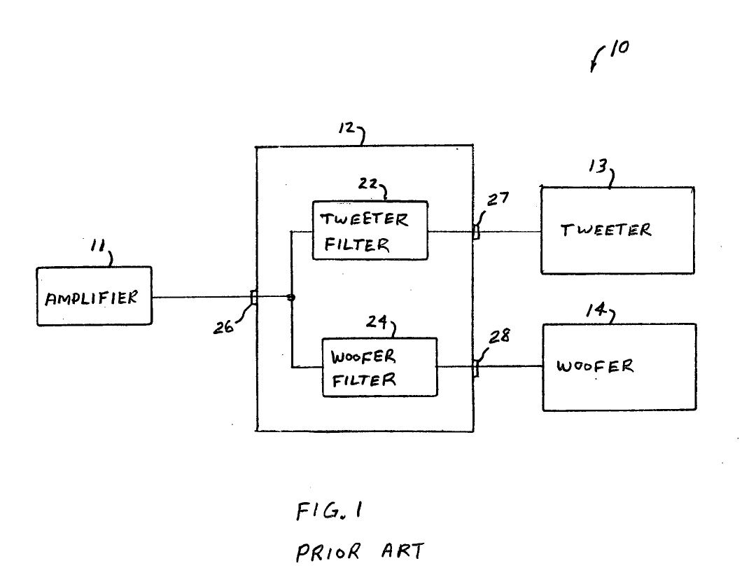

### DETAILED DESCRIPTION

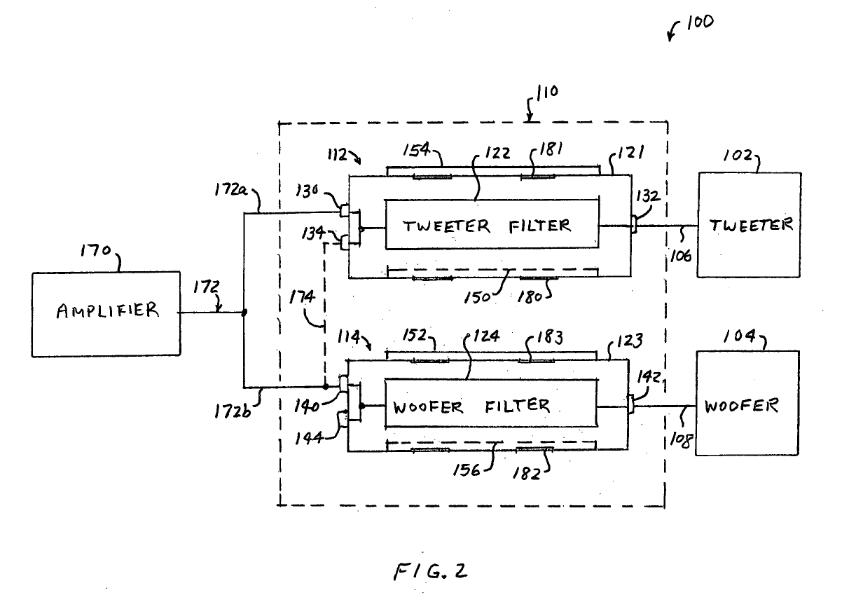

A schematic block diagram of a speaker 100 according to an embodiment of the invention is shown in FIG. 2. Speaker 100 includes a tweeter 102, a woofer 104, and a crossover assembly 110. Tweeter 102 is connected to crossover assembly 110 by a cable 106, and woofer 104 is connected to crossover assembly 110 by a cable 108.

Crossover assembly 110 includes a tweeter filter assembly 112 and a woofer filter assembly 114. Tweeter filter assembly 112 includes a tweeter filter housing 121 and a tweeter filter 122 mounted in tweeter filter housing 121. Tweeter filter assembly 112 further includes an input port 130, an output port 132 and an optional feedthrough port 134. Woofer filter assembly 114 includes a woofer filter housing 123 and a woofer filter 124 mounted in woofer filter housing 123. Woofer filter assembly 114 further includes an input port 140, an output port 142 and an optional feedthrough port 144.

The input, output and feedthrough ports may be coaxial or twin-wire electrical connectors. However, any suitable electrical connections may be utilized. In the embodiment of FIG. 2, the input and feedthrough ports are located at one end of each filter housing and the output port is located at the opposite end of each filter housing. However, the invention is not limited in this respect, and the input, output and feedthrough ports may be located on any suitable surface of each housing.

Tweeter filter assembly 112 further includes a mechanical connector 150, and woofer filter assembly 114 includes a mechanical connector 152. The mechanical connectors 150 and 152 are interengageable for mechanical docking of tweeter filter assembly 112 and woofer filter assembly 114. For example, mechanical connector 150 may be a female connector, and mechanical connector 152 may be a male connector, or vice-versa. In the embodiment of FIG. 2, tweeter filter assembly 112 includes female mechanical connector 150 on one side of tweeter filter housing 121 and a male mechanical connector 154 on the opposite side of tweeter filter housing 121. Similarly, woofer filter assembly 114 includes male mechanical connector 152 on one side of woofer filter housing 123 and a female mechanical connector 156 on the opposite side of woofer filter housing 123. This arrangement provides a high degree of flexibility in the docking of two or more filter assemblies as described below. Mechanical connectors 150, 152, 154, and 156 may be integral parts of the respective filter housings or may be individual mechanical connectors that are mounted to the respective housings.

Mechanical connectors 150, 152, 154, and 156 permit the tweeter filter assembly 112 and the woofer filter assembly 114 to be docked, or mechanically connected, together to form a unitary, docked crossover configuration. In some applications, the unitary, docked configuration may be advantageous with respect to mounting. The mechanical connectors also permit tweeter filter assembly 112 and woofer filter assembly 114 to be separated to form a separated crossover configuration. The separated configuration may be advantageous in applications where the tweeter 102 and the woofer 104 are mounted in separate locations and in applications where mounting of a single, larger crossover assembly is difficult or impossible. Thus, crossover assembly 110 has a feature wherein tweeter filter assembly 112 and woofer filter assembly 114 are dockable to form the docked crossover configuration and are separable to form the separated crossover configuration, thereby providing a high degree of versatility and flexibility.

By providing mechanical connectors on opposite sides of tweeter filter housing 121 and woofer filter housing 123, further versatility is achieved. Thus, woofer filter assembly 114 may be mounted on either side of tweeter filter assembly 112. Furthermore, additional filter assemblies may be mounted together in the docked configuration. For example, a midrange filter assembly may be utilized to provide a crossover assembly having three or more filter assemblies. The three or more filter assemblies may be utilized in a docked configuration, a partially docked configuration (wherein at least two of the filter assemblies are docked together), or a separated configuration.

Crossover assembly 110 may be connected to an amplifier 170 by a cable 172. Although amplifier 170 is illustrated as connected to tweeter filter assembly 112 and woofer filter assembly 114 by a single cable 172 having branches 172a and 172b, it will be understood that amplifier 170 may be connected to tweeter filter assembly 112 and woofer filter assembly 114 using any suitable electrical connection technique, including two separate cables. The term “cable” as used herein refers to any suitable electrical conduit, including but not limited to a coaxial cable, a twin-wire cable or separate electrical conductors. Branches 172a and 172b of cable 172 may be connected to input ports 130 and 140, respectively.

Speaker 100 corresponds to one branch of a speaker system. Typically, a speaker system includes two or more branches. Accordingly, in most applications an additional speaker (not shown), including a crossover assembly, a tweeter and a woofer, is used. While features and embodiments of the invention are discussed herein with reference to vehicle applications, the invention is not limited to vehicle applications and the principles of the invention may be utilized in any application in which a speaker is to be mounted.

Tweeter filter housing 121 may be any suitable housing for mounting and operating a tweeter filter. Tweeter filter 122 may be mounted in tweeter filter housing 121 using any suitable technique. The mounting technique may allow for removal of tweeter filter 122 without damage to tweeter filter 122 or tweeter filter housing 121. By way of example, tweeter filter 122 may be configured as a printed circuit board mounted on standoffs in tweeter filter housing 121.

Tweeter filter housing 121 may be made of any suitable material, preferably a material which is sufficiently durable to withstand shock and vibration that may occur in a specific application, such as in a vehicle, but which is sufficiently flexible to permit mounting to non-flat surfaces. Tweeter filter housing 121 may be provided with flanges, screw holes and/or other elements to facilitate mounting. In some embodiments, tweeter filter 122 may be thermally coupled to tweeter filter housing 121 to provide heat sinking. One of example of a suitable material for making tweeter filter housing 121 is aluminum.

Tweeter filter 122 receives the amplifier output signal from amplifier 170 via cable 172 and input port 130, and provides a filtered output signal to tweeter 102 via output port 132 and cable 106. Tweeter filter 122 may be any currently known or later-developed tweeter filter. As known in the art, tweeter filter 122 is configured to pass a high frequency portion of the audio frequency band.

As noted above, tweeter filter assembly 112 may include feedthrough port 134. As shown in FIG. 2, input port 130 and feedthrough port 134 may be electrically connected within tweeter filter housing 121. Accordingly, feedthrough port 134 provides an unfiltered amplifier output signal. For example, feedthrough port 134 may be used to provide a daisy chain connection between tweeter filter assembly 112 and woofer filter assembly 114. In this example, a cable 174, shown as a dashed line in FIG. 2, is connected between feedthrough port 134 of tweeter filter assembly 112 and input port 140 of woofer filter assembly 114. When the filter assembly inputs are daisy chained, branch 172a or branch 172b of cable 172 may be eliminated. Alternatively, cable 174 may be connected to feedthrough port 144 of woofer filter assembly 114. In another example, two or more tweeter filter assemblies can be daisy chained together using feedthrough port 134. A daisy chain connection may be advantageous to simplify wiring, particularly in applications where two or more filter assemblies are located relatively close together.

Woofer filter assembly 114 may have a similar construction to tweeter filter assembly 112, except that woofer filter 124 is mounted in woofer filter housing 123. As known in the art, woofer filter 124 is configured to pass a low frequency portion of the audio frequency band. Woofer filter 124 receives the amplifier output signal from amplifier 170 via cable 172 and input port 140, and provides a filtered output signal to woofer 104 via output port 142 and cable 108. Tweeter filter housing 121 and woofer filter housing 123 may be the same or different in size and shape.

In FIG. 2, tweeter filter assembly 112 and woofer filter assembly 114 are shown side-by-side. However, an aspect of the present invention is the ability to mount tweeter filter assembly 112 and woofer filter assembly 114 in any suitable locations, using the separated crossover configuration. In other applications, tweeter filter assembly 112 and woofer filter assembly 114 may be mounted next to one another and attached together, in the docked crossover configuration. As described above, tweeter filter assembly 112 includes mechanical connectors 150 and 154, and woofer filter assembly 114 includes mechanical connectors 152 and 156 to facilitate the separable and dockable feature of the crossover assembly.

Mechanical connectors 150, 152, 154, and 156 may be any suitable mechanical connectors for attaching tweeter filter assembly 112 and woofer filter assembly 114 together. For example, the mechanical connectors may be snap-fit or press-fit connectors. In some embodiments, the mechanical connectors may provide a rigid mechanical connection such that tweeter filter assembly 112 and woofer filter assembly 114 may be handled as a single unit during installation and mounting. A basic configuration includes a single mechanical connector on each of tweeter filter assembly 112 and woofer filter assembly 114, with the mechanical connectors being interengageable. Additional mechanical connectors may be added to each of tweeter filter assembly 112 and woofer filter assembly 114 to increase versatility of attachment. In some embodiments, the mechanical connectors may include electrical contacts for electrically connecting tweeter filter assembly 112 and woofer filter assembly 114, in addition to mechanical connection.

Tweeter filter assembly 112 may include vents 180 and 181 for cooling tweeter filter 122. Vents 180 and 181 may be located on opposite sides of tweeter filter housing 121 to permit cross flow of air. Woofer filter housing 123 may be provided with vents 182 and 183 for cooling woofer filter 124. Vents 182 and 183 may be located on opposite sides of woofer filter housing 123 to permit cross flow of air. Any suitable vent locations may be utilized, taking into consideration mechanical constraints and the expected mounting of the filter housings.

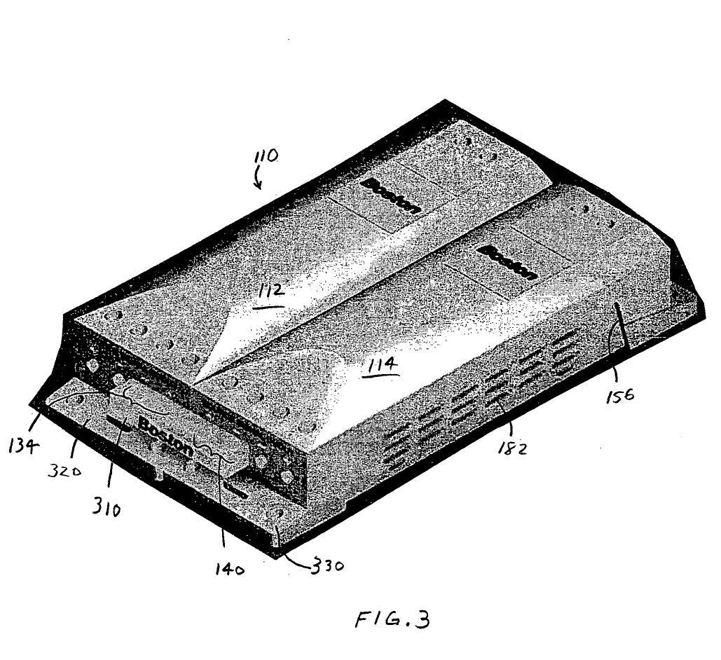

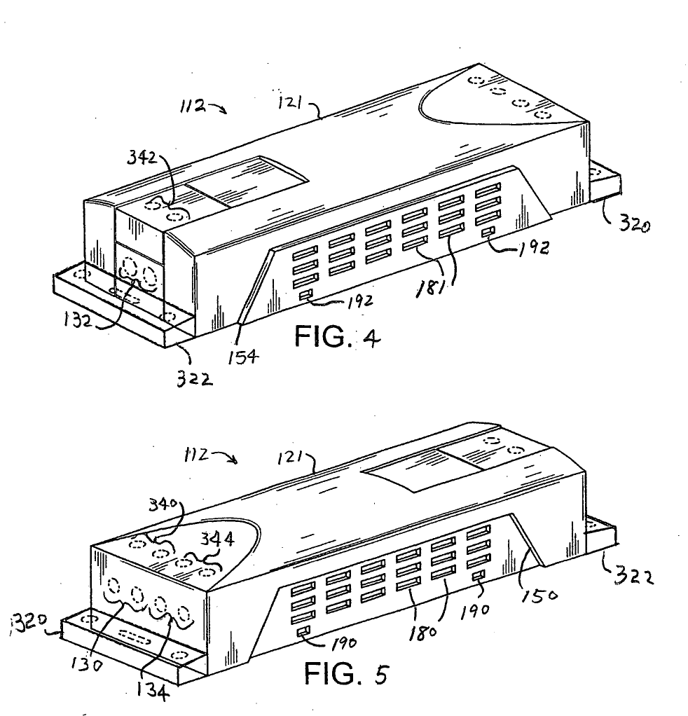

An implementation of crossover assembly 110 in accordance with an embodiment of the invention is shown in FIGS. 3-5. Like elements in FIGS. 2-5 have the same reference numerals. FIG. 3 is a perspective view of crossover assembly 110 in the docked configuration. FIG. 4 is a right-side perspective view of tweeter filter assembly 112, and FIG. 5 is a left-side perspective view of tweeter filter assembly 112.

As shown in FIG. 3, tweeter filter assembly 112 and woofer filter assembly 114 may be electrically connected together by an electrical connector 310. In the implementation of FIG. 3, electrical connector 310 is a rigid connector that connects feedthrough port 134 of tweeter filter assembly 112 to input port 140 of woofer filter assembly 114, such that tweeter filter 122 and woofer filter 124 are connected in parallel. In the implementation of FIG. 3, electrical connector 310 provides a two-wire connection between tweeter filter assembly 112 and woofer filter assembly 114. In the implementation of FIGS. 3-5, screws 340 may be utilized for fastening wires to input port 130; screws 342 may be utilized for fastening wires to output port 132; and screws 344 may be utilized for fastening wires to feedthrough port 134.

As shown in FIGS. 4 and 5, tweeter filter housing 121 may include female snap-fit connector 150 for mechanical connection to another housing, such as woofer filter housing 123. Tweeter filter housing 121 may further include male snap-fit connector 154 for connection to another filter housing (not shown in FIGS. 4 and 5).

In the implementation of FIGS. 3-5, male mechanical connector 154 on tweeter filter housing 121 includes a trapezoidal projection having a beveled edge and female mechanical connector 150 includes a matching trapezoidal recess having a beveled edge that is complementary to the beveled edge on connector 154. Connector 150 further includes tabs or projections 190, and connector 154 further includes complementary slots 192. Connectors 156 and 152 on woofer filter housing 123 may have the same configuration as connectors 150 and 154, respectively, on tweeter filter housing 121. When the male mechanical connector on one of the filter housings engages the female mechanical connector on the other of the filter housings, the trapezoidal projection slides into the trapezoidal recess, and tabs 190 snap into slots 192. The beveled edges of the trapezoidal projection and the trapezoidal recess prevent the filter housings from coming apart. It will be understood that the above mechanical connector configuration is given by way of example only and is not limiting as to the present invention. Other mechanical connector configurations may be utilized.

Tweeter filter housing 121 may be provided with mounting brackets 320 and 322 for mechanically attaching tweeter filter assembly 112 to a suitable surface, such as a surface of a vehicle. Woofer filter housing 123 may be provided with mounting brackets 330 and 332 for mechanically attaching woofer filter assembly 114 to a suitable surface, such as a surface of a vehicle. Mounting brackets 320, 322, 330 and 332 may be utilized for mounting of the respective filter assemblies in both the docked and separated configurations. It will be understood that other mounting bracket configurations may be utilized within the scope of the invention.

As further shown in FIGS. 3-5, vents 180, 181 may be implemented as a plurality of slots in tweeter filter housing 121. The slots permit crossflow of air across tweeter filter 122. Woofer filter housing 123 may have a similar configuration.

In one example, tweeter filter housing 121 or woofer filter housing 123 may have approximate dimensions of 1.5 inches in height, 2.0 inches in width and 5.0 inches in length. By contrast, a prior art crossover housing may have a width of about 3 inches. Accordingly, a single tweeter filter assembly or woofer filter assembly according to embodiments of the present invention may have a smaller footprint on a mounting surface than a prior art crossover housing. Accordingly, in applications where space is limited, more options are available for mounting a tweeter filter assembly or woofer filter assembly according to the present invention. Thus, a tweeter filter assembly and a woofer filter assembly according to the present invention may be more conveniently located within a vehicle.

Additionally, the mounting options may allow a tweeter filter assembly to be mounted closer to the tweeter, and/or a woofer filter assembly to be mounted closer to the woofer. Accordingly, the length of the cable used to connect a tweeter filter assembly to a tweeter and/or to connect a woofer filter assembly to a woofer may be reduced. Such reduction in length may result in a reduction in electromagnetic interference on the tweeter driver signal and/or the woofer driver signal, and may reduce the impedance of the cables used to make the connections. The reduced interference and reduced impedance may improve the sound characteristics of the tweeter and/or the woofer. Accordingly, crossover assemblies according to embodiments of the present invention provide a designer with options that may allow specific performance goals to be met.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

1. A crossover assembly for connection in an audio system including an amplifier and two or more transducers, comprising:
a first filter assembly including a first filter mounted in a first housing; and
a second filter assembly including a second filter mounted in a second housing, wherein the first and second filter assemblies are mechanically dockable to form a single crossover unit and wherein the first and second filter assemblies are mechanically separable to facilitate mounting in different locations.

2. A crossover assembly as defined in claim 1, wherein the first filter comprises a tweeter filter and wherein the second filter comprises a woofer filter.

3. A crossover assembly as defined in claim 1, wherein the first filter assembly includes a first mechanical connector and wherein the second filter assembly includes a second mechanical connector, wherein the first and second mechanical connectors are interengageable for mechanical docking of the first and second filter assemblies and are disengageable for mechanical separation of the first and second filter assemblies.

4. A crossover assembly as defined in claim 3, wherein the first and second mechanical connectors comprise snap-fit connectors.

5. A crossover assembly as defined in claim 3, wherein the first and second mechanical connectors comprise integral components of the first and second housings, respectively.

6. A crossover assembly as defined in claim 1, wherein the first and second filter assemblies each include an input port and an output port.

7. A crossover assembly as defined in claim 6, wherein at least one of the first and second filter assemblies includes a feedthrough port.

8. A crossover assembly as defined in claim 3, wherein the first and second filter assemblies have a common mechanical connector configuration.

9. A crossover assembly as defined in claim 7, further comprising an electrical connector for interconnecting the feedthrough port on one filter assembly and the input port on the other filter assembly.

10. A crossover assembly as defined in claim 1, wherein the first housing and the second housing have equal sizes.

11. A crossover assembly as defined in claim 1, wherein the first housing and the second housing have different sizes.

12. A crossover assembly for connection in an audio system including an amplifier and two or more transducers, comprising:
a tweeter filter assembly including a tweeter filter housing, a tweeter filter mounted in the tweeter filter housing, an input port, an output port and a first mechanical connector; and
a woofer filter assembly including a woofer filter housing, a woofer filter mounted in the woofer filter housing, an input port, an output port and a second mechanical connector, wherein the tweeter and woofer filter assemblies are dockable by interengaging the first and second mechanical connectors and are separable by disengaging the first and second mechanical connectors.

13. A crossover assembly as defined in claim 12, wherein the first and second mechanical connectors comprise snap-fit connectors.

14. A crossover assembly as defined in claim 13, wherein the first and second mechanical connectors are integral components of the respective housings and wherein the tweeter filter housing and the woofer filter housing are dockable.

15. A crossover assembly as defined in claim 12, wherein at least one of the filter assemblies includes a feedthrough port for interconnection to the input port of the other filter assembly.

16. A crossover assembly as defined in claim 12, wherein the tweeter filter assembly and the woofer filter assembly are mechanically separable, by disengaging the first and second mechanical connectors, for separate mounting.

17. A filter assembly for connection in an audio system including an amplifier and a transducer, comprising:
a filter housing including a mechanical connector;
a single crossover filter mounted in the filter housing;
an input port for connecting the crossover filter to the amplifier; and
an output port for connecting the crossover filter to the transducer, wherein the filter assembly is mechanically dockable to another filter assembly using the mechanical connector.

18. A filter assembly as defined in claim 17, wherein the mechanical connector comprises a snap-fit connector.

19. A filter assembly as defined in claim 17, wherein the mechanical connector comprises an integral component of the filter housing.

20. A filter assembly as defined in claim 17, further comprising a feedthrough port for electrically connecting the filter assembly to another filter assembly.

21. A filter assembly as defined in claim 17, wherein the filter housing includes first and second mechanical connectors on opposite sides thereof.

22. A filter assembly as defined in claim 17, wherein the filter housing includes one or more vents.

23. A filter assembly as defined in claim 17, wherein the filter housing further comprises at least one mounting flange.

24. A filter assembly as defined in claim 17, wherein the filter housing further comprises mounting flanges at opposite ends thereof.
